(19) United States
(12) Patent Application Publication
(10) Pub. No.: US 2007/0272932 A1
(43) Pub. Date: Nov. 29, 2007

(54) Light-emitting diode with improved ultraviolet light protection

(76) Inventors: Chua Bee Yin Janet, Perak (MY); Tan Kheng Leng, Penang (MY)

Correspondence Address: Kathy Manke;Avago Technologies Limited, 4380 Ziegler Road, Fort Collins, CO, 80525, US

(21) Appl. No.: 11/430,288

(22) Filed: May 8, 2006

(51) Int. Cl. H01L 33/00; H01L 31/12; H01L 27/15; H01L 29/26

(52) U.S. Cl. 257/79

(57) ABSTRACT

The present application relates to a semiconductor device comprising one or more protective layers, and more specifically to a light-emitting diode comprising one or more ultraviolet protective layers. The use of said UV protective layers prevents the degradation of a LED by UV light. This results in a LED with improved UV protection, and consequently, wit

[symbol]

### CROSS-REFERENCE TO RELATED APPLICATIONS

Not applicable.

### TECHNICAL FIELD

The application relates in general to a semiconductor device and more particularly to a light-emitting diode (LED) comprising one or more ultraviolet (UV) protective layers.

### BACKGROUND OF THE INVENTION

Conventional LEDs generally comprise a light-emitting diode chip at least partially encapsulated by an encapsulant. Common LED encapsulation systems or encapsulants comprise an epoxy or a silicone material.

One drawback with conventional LED is that the LED encapsulant absorbs UV light. Prolonged exposure to UV light causes degradation of the encapsulant material and reduced light extraction by the encapsulant. UV light sources can be internal or external. Additionally, as a result of decreasing light extraction, more and more UV light is absorbed by the encapsulant when an internal UV light source is present. In all cases, however, exposure of conventional LED to UV light causes degradation of the encapsulant, which results in inevitable failure of the LED.

### BRIEF SUMMARY OF THE INVENTION

Embodiments of the invention involve a semiconductor device comprising one or more protective layers, more specifically a LED comprising one or more UV protective layers. The UV protective layers inhibit the degradation of LED components susceptible to UV light, for example the encapsulant. In one embodiment, a LED comprises a UV protective layer deposited on the surface of the encapsulant, wherein the UV protective layer inhibits UV light emitted from an exterior source from infiltrating said encapsulant. In another embodiment, a LED comprises a UV protective layer deposited between the LED chip and the encapsulant, wherein the UV protective layer inhibits UV light emitted by an internal source from infiltrating said encapsulant. In another embodiment, a first UV protective layer, deposited between the LED chip and the encapsulant, and a second UV protective layer, deposited on the surface of the encapsulant, inhibit UV light emitted from internal and external sources, respectively, from infiltrating said encapsulant. Therefore LEDs, according to embodiments of the invention, are less susceptible to UV light, and therefore, are suitable for use in the presence of one or more UV light sources.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 is a cross-section of one embodiment of the invention where a UV protective layer has been deposited on the surface of the encapsulant.

FIG. 2 is a cross-section of another embodiment of the invention where a UV protective layer has been deposited on the surface of the LED chip; and

FIG. 3 is a cross-section of a further embodiment of the invention where a first UV protective layer has been deposited on the surface of the LED chip and a second UV protective layer has been deposited on the surface of the encapsulant.

### DETAILED DESCRIPTION OF THE INVENTION

The invention comprises a semiconductor device, more specifically a LED, with one or more protective layers. LED comprising one or more UV protective layers will now be described in detail while referring to the drawings.

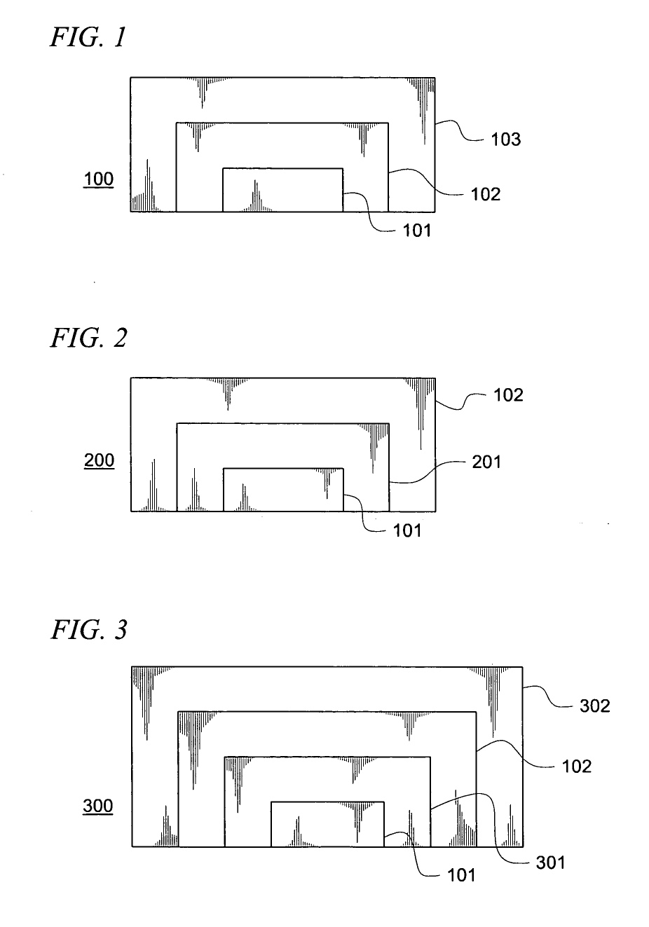

As shown in FIG. 1, the LED 100 has a LED chip 101 encapsulated at least partially by an encapsulant 102. The LED chip 101 can be any commercially available LED chip. The encapsulant 102 comprises any suitable transparent material known in the art that coats and protects LED chip 101. For example, it can comprise an epoxy or a siloxane material. A UV protective layer 103 at least partially covers encapsulant 102. The UV protective layer 103 comprises any suitable UV protective material which can be deposited on at least part of the surface of encapsulant 102. For example, the UV protective material can be deposited as a thin film on the surface of the encapsulant 102. Suitable UV protective material can be any material that protects against or inhibits the infiltration of UV light into the encapsulant, for example Spin on Glass (SOG), while being transparent to the light wavelengths of interest from the LED 101. Additionally, an adhesion promoter may be deposited along with the UV protective material to aid in the adhesion of the UV protective material to the encapsulant.

As discussed previously, an encapsulant susceptible to UV light will degrade upon prolonged exposure to a UV light source. In the embodiment shown in FIG. 1, the UV protective layer 103 inhibits UV light emitted from an external source from infiltrating the LED, and thereby, from being absorbed by and degrading the encapsulant 102. Possible external sources of UV light can be the sun or another LED, among others.

As shown in FIG. 2, the LED 200 has a LED chip 101 covered at least partially by a UV protective layer 201. The UV protective layer 201 is encapsulated at least partially by an encapsulant 102. Suitable examples of or materials for LED chip 101, UV protective layer 201 and encapsulant 102 are as previously described for LED chip 101, UV protective layer 103 and encapsulant 102, respectively, in FIG. 1.

In the embodiment shown in FIG. 2, the UV protective layer 201 inhibits UV light from an internal source from infiltrating, and thereby degrading, the encapsulant 102. Possible internal sources of UV light can be the LED chip 101, among others.

As shown in FIG. 3, the LED 300 has a LED chip 101 covered at least partially by a first UV protective layer 301. The UV protective layer 301 is encapsulated at least partially by an encapsulant 102. The encapsulant 102 is covered at least partially by a second UV protective layer 302. Suitable examples of or materials for LED chip 101, UV protective layers 301 and 302, and encapsulant 102 are as previously described for LED chip 101, UV protective layer 103, and encapsulant 102, respectively, in FIG. 1.

In the embodiment shown in FIG. 3, the first UV protective layer 301 inhibits UV light from an internal source from infiltrating, and thereby degrading, the encapsulant 102 while the second UV protective layer 302 inhibits UV light from an external source from infiltrating, and thereby degrading, the encapsulant 102.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of the ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a semiconductor chip;
an encapsulant at least partially encapsulating said semiconductor chip; and
a protective layer at least partially covering the exterior surface of said encapsulant.

2. The semiconductor device of claim 1, wherein said semiconductor chip comprises a light-emitting diode chip.

3. The semiconductor device of claim 1, wherein said encapsulant comprises an epoxy compound.

4. The semiconductor device of claim 1, wherein said encapsulant comprises a silicone compound.

5. The semiconductor device of claim 1, wherein said protective layer inhibits the infiltration of UV light.

6. The semiconductor device of claim 1, wherein said protective layer comprises Spin on Glass.

7. The semiconductor device on claim 6, further comprising an adhesion promoter associated with said protective layer.

8. A semiconductor device comprising:
a semiconductor chip;
a protective layer at least partially covering the exterior surface of said semiconductor chip; and
an encapsulant at least partially encapsulating said protective layer on said semiconductor chip.

9. The semiconductor device of claim 8, wherein said semiconductor chip comprises a light-emitting diode chip.

10. The semiconductor device of claim 8, wherein said encapsulant comprises an epoxy compound.

11. The semiconductor device of claim 8, wherein said encapsulant comprises a silicone compound.

12. The semiconductor device of claim 8, wherein said protective layer inhibits the infiltration of UV light.

13. The semiconductor device of claim 8, wherein said protective layer comprises Spin on Glass.

14. The semiconductor device of claim 13, further comprising an adhesion promoter associated with said protective layer.

15. A semiconductor device comprising:
a semiconductor chip;
a first protective layer at least partially covering the exterior surface of said semiconductor chip;
an encapsulant at least partially encapsulating said first protective layer on said semiconductor chip; and
a second protective layer at least partially covering the exterior surface of said encapsulant.

16. The semiconductor device of claim 15, wherein said semiconductor chip comprises a light-emitting diode chip.

17. The semiconductor device of claim 15, wherein said encapsulant comprises an epoxy compound.

18. The semiconductor device of claim 15, wherein said encapsulant comprises a silicone compound.

19. The semiconductor device of claim 15, wherein one or more of said first and second protective layers inhibit the infiltration of UV light.

20. The semiconductor device of claim 15, wherein one or more of said first and second protective layers comprise Spin on Glass.
